(19) United States
(12) Patent Application Publication
(10) Pub. No.: US 2026/0053019 A1
(43) Pub. Date: Feb. 19, 2026

(54) ADAPTIVE THREE-DIMENSIONAL CIRCUIT ATTACHMENT

(71) Applicant: Intel Corporation, Santa Clara, CA (US)

(72) Inventors: Terry William GILMORE, Ridgefield, WA (US); Daniel KLOWDEN, Portland, OR (US)

(21) Appl. No.: 19/370,793

(22) Filed: Oct. 28, 2025

Related U.S. Application Data
(60) Provisional application No. 63/854,533, filed on Jul. 31, 2025.

(51) Int. Cl. H01L 23/538; H01L 21/304; H01L 23/00; H01L 25/065

(52) U.S. Cl. CPC H01L 23/5387; H01L 21/3043; H01L 24/29; H01L 24/32; H01L 25/0652; H01L 2224/29191; H01L 2224/32225

(57) ABSTRACT

Various aspects relate to three-dimensional integrated circuits including a plurality of conformal integrated circuit slices stacked one upon the other. The plurality of conformal integrated circuit slices includes various components. A communication face defines a communication surface configured to conform to a portion of a topography of a non-planar host substrate. A plurality of input-output devices is configured to communicate to a corresponding plurality of host-side input-output devices associated with the non-planar host substrate.

### CROSS-REFERENCE TO RELATED APPLICATION

This application claims priority to U.S. Provisional Patent Application No. 63/854,533 filed on Jul. 31, 2025, the contents of which is fully incorporated herein by reference.

### BACKGROUND

In general, three-dimensional heterogeneous integration involves combining different types of semiconductor implementations into a single, three-dimensional package. Approaches to three-dimensional heterogeneous integration techniques face significant limitations in the physical attachment of structures, especially when these structures are rotated, edge-mounted, or otherwise oriented outside of traditional face-down packaging geometries. As integration density increases and dies are assembled in non-planar or cube-style configurations, conventional bonding and/or attachment techniques become difficult to scale, align, or rework. Specifically, existing methods fail to address several challenges. Precision lateral alignment of cube structures to host substrates in the presence of thermal expansion can be difficult, especially with respect to host substrate warpage, thermal expansion, and mechanical misalignment under operating conditions. Accordingly, there is a need for new structural attachment strategies tailored for edge oriented three-dimensional cubes, enabling secure, repeatable, and high yield integration across varying substate types and die topologies.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the proposed configuration. In the following description, various aspects are described with reference to the following drawings, in which:

FIG. 1A depicts an example portion of the topography of a host substrate for interfacing with a three-dimensional integrated circuit in an X-Y spatial plane;

FIG. 1B depicts an example portion of the topography of a host substrate in a Y-Z spatial plane;

FIG. 2A depicts an example front view of a stack of slices in a three-dimensional integrated circuit disposed upon a host substrate at room temperature;

FIG. 2B depicts an example isometric view of a stack of slices in a three-dimensional integrated circuit disposed upon a host substrate at room temperature;

FIG. 2C depicts an example front view of a stack of slices in a three-dimensional integrated circuit disposed upon a host substrate at operating temperature;

FIG. 2D depicts an example isometric view of a stack of slices in a three-dimensional integrated circuit disposed upon a host substrate at operating temperature;

FIG. 3A depicts an example side view of a slice of a three-dimensional integrated circuit with inductive couplers placed in a horizontal line that is coplanar to a flat top surface of the slice;

FIG. 3B depicts an example side view of a slice of a three-dimensional integrated circuit with inductive couplers placed in curved configuration that generally follows a conforming face of the slice;

FIG. 4A depicts an example front view of a stack of slices in a three-dimensional integrated circuit disposed upon a host substrate with coplanar inductors at operating temperature;

FIG. 4B depicts an example isometric view of a stack of slices in a three-dimensional integrated circuit disposed upon a host substrate with coplanar inductors at operating temperature;

FIG. 5A depicts an example front view of a stack of slices in a three-dimensional integrated circuit disposed upon a host substrate with conforming inductors at operating temperature;

FIG. 5B depicts an example isometric view of a stack of slices in a three-dimensional integrated circuit disposed upon a host substrate with conforming inductors at operating temperature;

FIG. 6A depicts an example top view of a patterned wafer with a row of dies corresponding to slices for a three-dimensional integrated circuit that have been diced according to a conforming pattern to conform to a non-planar host substrate;

FIG. 6B depicts an example isometric view of a row of die edges in a dicing lane on a patterned wafer corresponding to slices for a three-dimensional integrated circuit that have been diced according to a conforming pattern to conform to a non-planar host substrate;

FIG. 7A depicts an example side view of a stack of slices in a three-dimensional integrated circuit disposed upon a host substrate at operating temperature;

FIG. 7B depicts an example isometric view of a stack of slices in a three-dimensional integrated circuit disposed upon a host substrate at operating temperature;

FIG. 8A depicts an example expanded isometric view of a stack of slices in a three-dimensional integrated circuit disposed upon a host substrate at operating temperature with a shim;

FIG. 8B depicts an example expanded isometric view of a stack of slices in a three-dimensional integrated circuit disposed upon a host substrate at operating temperature to illustrate communication faces of conforming slices;

FIG. 9A depicts an example locking groove around a stack of slices;

FIG. 9B depicts an example band of formed bonding agent in a groove around a stack of slices in a three-dimensional integrated circuit disposed upon a host substrate at operating temperature;

FIG. 9C depicts an example trench of formed bonding agent in a groove around a stack of slices in a three-dimensional integrated circuit disposed upon a host substrate at operating temperature;

FIG. 9D depicts an example cap of formed bonding agent in a groove around a stack of slices in a three-dimensional integrated circuit disposed upon a host substrate at operating temperature;

FIG. 10A depicts an isometric view of an example jig and forming device for bonding agent in a groove around a stack of slices in a three-dimensional integrated circuit disposed upon a host substrate at operating temperature;

FIG. 10B depicts a front view of an example jig and forming device for bonding agent in a groove around a stack of slices in a three-dimensional integrated circuit disposed upon a host substrate at operating temperature;

FIG. 10C depicts a side view of an example jig and forming device for bonding agent in a groove around a stack of slices in a three-dimensional integrated circuit disposed upon a host substrate at operating temperature;

FIG. 11A depicts a side view of an example jig and forming device for bonding agent in a groove around a stack of slices in a three-dimensional integrated circuit disposed upon a host substrate at operating temperature;

FIG. 11B depicts another isometric view of an example jig and forming device for bonding agent in a groove around a stack of slices in a three-dimensional integrated circuit disposed upon a host substrate at operating temperature;

FIG. 12A depicts an example flexible interface for flexibly supporting a stack of slices in a three-dimensional integrated circuit with a laterally connected flexible interface structure connected laterally to a substrate;

FIG. 12B depicts an example flexible interface for flexibly supporting a stack of slices in a three-dimensional integrated circuit with a laterally connected interface structure connected to a substrate;

FIG. 12C depicts flexible interface for flexibly supporting a stack of slices in a three-dimensional integrated circuit with a laterally connected interface structure connected to a substrate; and

FIG. 12D depicts flexible interface for flexibly supporting a stack of slices in a three-dimensional integrated circuit with a laterally connected interface structure connected to a substrate.

### DESCRIPTION

The following detailed description refers to the accompanying drawings that show, by way of illustration, specific details and aspects in which the proposed configuration may be practiced. These aspects are described in sufficient detail to enable those skilled in the art to practice the proposed configuration. Other aspects may be utilized and structural, logical, and electrical changes may be made without departing from the scope of the proposed configuration. The various aspects are not necessarily mutually exclusive, as some aspects may be combined with one or more other aspects to form new aspects. Various aspects are described in connection with methods and various aspects are described in connection with devices (e.g., a memory module, a computing system). However, it is understood that aspects described in connection with methods may apply in a corresponding manner to the devices, and vice versa.

As three-dimensional heterogeneous integration (3DHI) architectures evolve to support vertically stacked chiplets and cube-style structures, host to cube attachment methods need to account for host substrate warpage, thermal expansion, and mechanical misalignment under operating conditions. These mechanics may create physical gaps between inductive coupling communication interfaces, degrade signal and power coupling, and introduce mechanical stress that may negatively impact system reliability.

Moreover, conventional bonding and packaging approaches, such as rigid die attach, planar soldering, or static underfill, are not designed to accommodate non-planar surfaces, dynamic alignment, or contactless coupling. Contactless coupling, which may be implemented as inductive coupling provides an induction-based wireless integrated circuit interconnection that may transfer power and/or data between integrated circuits using electromagnetic fields. Such an approach avoids the use of physical wires by leveraging the principle of inductive coupling, as used in alternating-current transformers, where a changing magnetic field in a first inductor induces a voltage in a second inductor. In the case of high-speed and relatively low-power application of inductive coupling between a host substrate and a three-dimensional integrated circuit, the first and second inductors ideally will be separated by as little as a few micrometers. In practice, such a distance between communicating inductors should not be more than a relatively short distance, such as ten micrometers, or in some cases twenty micrometers. In addition to inductive communication, input and output communications may similarly be provided in connection with input-output devices that communicate using capacitive wireless communication or direct electrical connections. In various aspects, direct electrical connections may be facilitated by mechanical devices that apply mechanical forces to complete electrical connections between two communication devices, such as, for example pogo pins, which use a spring-loaded plunger inside a barrel to make a temporary electrical connection. When pressure is applied, the spring compresses, and the plunger moves into the barrel to connect with a mating surface or pad.

In order to maintain communicating input-output devices, such as the non-contact inductors, in close proximity, systems of topography-conforming, three-dimensional heterogeneous integration slices face challenges adapting to warped or thermally deformed shapes of host substrates. Such inductive coupling techniques may implement input-output devices in integrated circuits allowing multiple integrated circuits to wirelessly communicate with each other using semiconductor based inductive couplers and associated transistor logic to drive signals to and from the inductive couplers, by way of driver circuitry implemented in the transistor logic.

Topography-conforming, three-dimensional integrated circuits may provide mechanisms for shaping a communication face of a vertically stacked three-dimensional heterogeneous integration cube to conform to the topography of a warped or thermally dynamic host substrate. Using room-temperature and/or simulated and/or modeled operating conditions of a host substrate, the communication face of each individual slice in a cube may be cut or patterned to match an expected deformation profile of a particular host substrate. This ensures a minimal gap and optimal signal interfaces between the cube and host at a range of operating conditions, such as for example between 40 degrees Celsius and 60 degrees Celsius. Alternative operating conditions can be between 60 degrees Celsius and 70 degrees Celsius or even above 70 degrees Celsius.

Topography-conforming locking mechanisms provide various locking structures that use conductive or non-conductive bonding agents to align and secure a three-dimensional integrated circuit stack to itself and/or to a host substrate. Such locking mechanisms include band locking structures, trench locking structures, and cap locking structures. Geometric notches or etched features may be etched into portions of die egest, or perimeter areas of slices, to increase mechanical interlock with encapsulant or bonding agents. These mechanisms may be applied in-situ or off-substrate using a topography-matching jig and are compatible with plasma-etched communication faces or conforming slices guided by topography-conforming, three-dimensional integrated circuit structures.

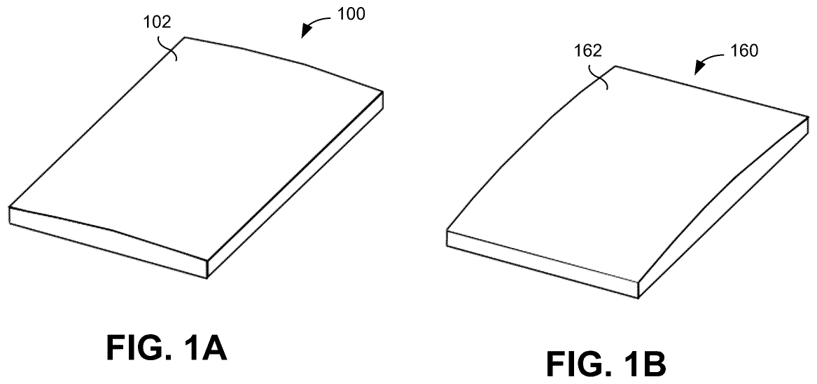

FIG. 1A depicts an example portion 100 of the topography of a host substrate for interfacing with a three-dimensional integrated circuit in an X-Y spatial plane. FIG. 1B depicts an example portion of the topography of a host substrate in a Y-Z spatial plane. In general, host substrate topography may vary at operating temperatures, even if at room temperature a host substrate would be substantially flat. Topography-conforming, three-dimensional integrated circuit designs begin with a characterization of a surface topography of a particular host substrate under both room-temperature and operating conditions. An objective is to capture an actual shape of a host substrate when it is in operation, including any thermomechanical deformation in all three spatial planes (X-Y, Y-Z, and Z-X). Topography can be measured directly using tools such as optical profilometers, atomic force microscopes (AFM), or laser scanning confocal microscopes. Alternatively, modeling tools can be used to simulate warpage using material stack parameters and thermal expansion coefficients. The resulting data provides a deformation map of the host substrate, which can be used to guide the shaping of the communication face of each individual three-dimensional integrated circuit slice. The host substrate might be warped in any of the three spatial planes as shown in FIGS. 1A and 1B. The Z-X plane is not shown below but a warped die in this plane would cause a shape without four 90-degree corners.

In various aspects, a particular host substrate design, in production, will have adequate similarity that scanning or modeling a sample of substrates will result in a geometry that can be used in connection with cubes that are designed to work in connection with the particular host substrate design. In other aspects, certain batches of a production run of a host substrate can be scanned and custom cubes produced to conform to a geometry of that batch. In yet other aspects, a custom cube geometry may be produced on a bespoke basis to conform to an individually scanned substrate to produce bespoke paired geometries of host substrates individually matched to conforming integrated circuit cube model.

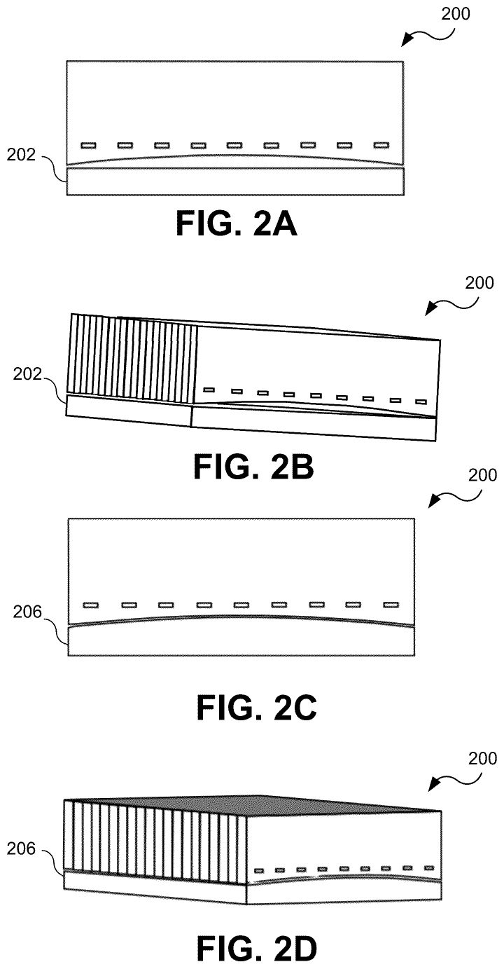

FIG. 2A depicts an example front view of a stack 200 of slices in a three-dimensional integrated circuit disposed upon a host substrate 202 at room temperature, in which the host substrate 202 is shown to be substantially flat. FIG. 2B depicts an example isometric view of a stack 200 of slices in a three-dimensional integrated circuit disposed upon a host substrate 202 at room temperature. FIG. 2C depicts an example front view of a stack 200 of slices in a three-dimensional integrated circuit disposed upon a host substrate 204 at operating temperature. FIG. 2D depicts an example isometric view of a stack of slices in a three-dimensional integrated circuit disposed upon a host substrate 204 at operating temperature. To conform a cube's communication surface to that of a warped host substrate, the communication-face may be adapted by forming and/or cutting the individual slices by way of transposing the host substrate's topography onto each slice's communication edge, so that once the three-dimensional integrated circuit reaches operating conditions, the distances between said host substrate face and cube/individual slice faces expand and or contract to reduce any gap between components as seen in FIG. 2A, FIG. 2B, FIG. 2C, and FIG. 2D. In various aspects, expansion joint engineering may be deployed to facilitate a proper fit between a conforming cube and a corresponding warped host substrate. It is understood that a host substrate can also form valleys rather than hills, or any variation of undulating surfaces. The resulting dies would then be cut to match topographies at operating conditions of those geometries.

For the purpose of illustration only, warped host substrates are shown in convex form, however, as noted, any number of many various topographies is possible. In addition, it may occur that a particular host substrate may also be non-flat or warped while at room temperature, then flatten once at operating conditions. In such a case, the three-dimensional integrated circuit could float on top of the warped host substrate with the help of a socketing device. As the host-die flattened during operating conditions, the three-dimensional integrated circuit would naturally float down to conform to the host substrate face, reducing physical separation between the host substrate and three-dimensional integrated circuit input-output structures. A corresponding socketing device would either actively or passively drive the three-dimensional integrated circuit down as the host substrate flattened under operating conditions.

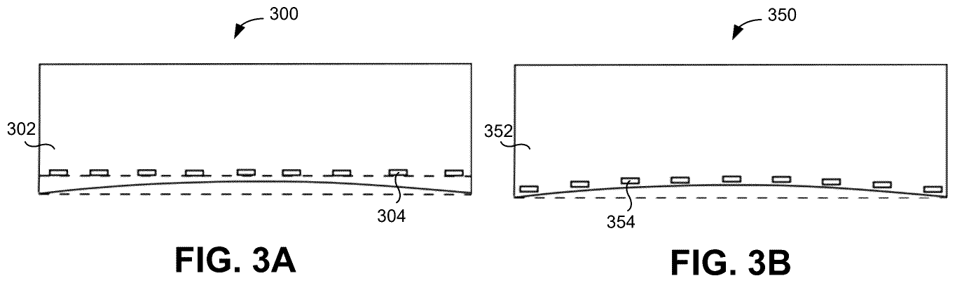

FIG. 3A depicts an example side view of a slice 300 of a three-dimensional integrated circuit with inductive couplers 302 placed in a horizontal line that is coplanar to a flat top surface of the slice. In various aspects, a top surface of slice 300 may not be flat, in such a case, the linear/planar set of inductive couplers 302 may be formed in a line that is substantially tangential to a feature of communication face 304. In various aspects, where a communication face is concave, a linear set of input-output devices or inductive couplers 302 may be tangential to a local maximum of communication face 304. In other aspects, for a convex communication face 304, the linear set of input-output devices would be tangential to a local minimum of the downwardly curved communication face.

FIG. 3B depicts an example side view of a slice 350 of a three-dimensional integrated circuit with inductive couplers 352 placed in curved configuration that generally follows conforming face 354 of the slice. As shown in connection with FIG. 3A and FIG. 3B, conforming slices may have inductive communicators 302 and 352 (wireless input-output ports) that follow various form factors. Linear path conforming slices keeps an input-output (inductor) location fixed and colinear across slices, allowing the etched communication face to shift independently of the input-output pattern as seen in FIG. 3A. Such an approach simplifies mask design and maximizes spacing between input and output inductors and the etched edge, reducing risks of damaging inductive coupling circuitry during plasma dicing. It is ideal for supporting a broad range of host substrate topographies without requiring per-slice lithography variation. Advantages of the design of FIG. 3A include keeping inductive couplers colinear as to provide maximum space between them and the communication face of a slice before the slice is cut, allowing for the widest margin between inductive coupling circuitry and a cut.

FIG. 3B has inductive couplers 352 that conform to communication face 354 of slice 350. Advantages of the design of FIG. 3B include keeping inductive couplers as close as possible to the corresponding inductive couplers in a host substrate. However, producing specially spaced inductive couplers may be more complicated and therefore more costly. Moreover, having them closer to the edge of a slice risks damage to the inductive couplers during separation or singulation of a slice.

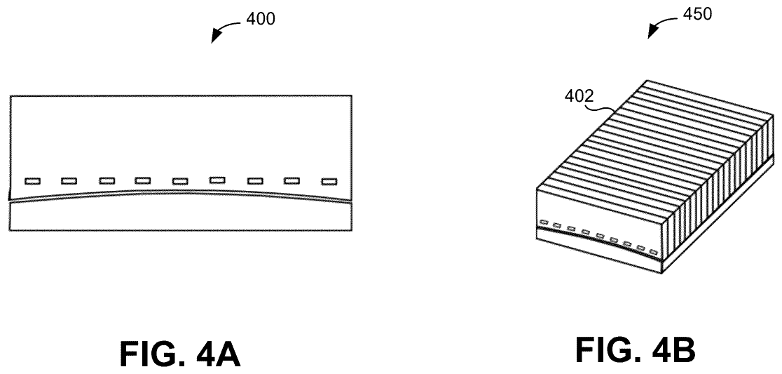

FIG. 4A depicts an example front view of a stack of slices 402 in a three-dimensional integrated circuit disposed upon a host substrate with coplanar inductors at operating temperature. 4B depicts an example isometric view of a stack of slices in a three-dimensional integrated circuit disposed upon a host substrate with coplanar inductors at operating temperature. As noted above, co-planar, linear path conforming slices keeps a input-output (inductor) location fixed and colinear across slices and provides an extra margin of error when forming a conforming profile in a slice, however, when little or none of the extra slice material, the inductive coupler is necessarily further from the host substrate, which may result in communications problems if the distance is too great.

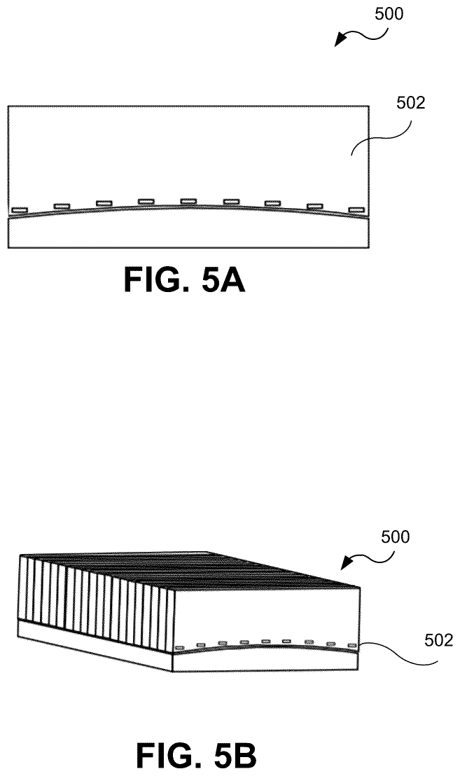

FIG. 5A depicts an example front view of a stack 500 of slices in a three-dimensional integrated circuit disposed upon a host substrate with conforming inductors at operating temperature. FIG. 5B depicts an example isometric view of a stack 500 of slices in a three-dimensional integrated circuit disposed upon a host substrate with conforming inductors at operating temperature. Manhattan curve-based conforming slices may be provided for higher precision alignment. Such a design approach approximates curved communication faces using Manhattan geometries over keeping the inductive communicators in a colinear path (as described in connection with FIGS. 4A and 4B above). Here, the input-output locations follow the etched face more closely as seen in FIG. 5A and FIG. 5B, enabling reduced signal path length and better physical matching. However, it increases mask count and process complexity due to customization based on the expected min/max warpages of host substrates and their variability. This design is best suited for minimizing input-output distance between the cube and host substrate as seen in FIG. 5A and FIG. 5B. While true arc-based patterning is possible in photolithography, it introduces complexity, resolution challenges, and overlay risks-particularly at the reticle and stepper level. Moreover, many semiconductor fabs do not natively support curved geometries in mask tooling or process control. To address these limitations, Manhattan polygonal approximations may be employed to construct communication faces of slices. This approach allows inductive communicators to follow a stepped approximation of the intended curve, rather than the slope of the true arc, enabling manufacturable, topography-conforming geometries using standard fab tools. Manhattan curves can approximate virtually any surface topology with sufficient resolution and mask precision. It is understood that the curve of the communication face of a slice could protrude outwardly, rather than being cut into the slice to conform to valleys rather than hills. In such cases, the geometries would be reversed, and any combination of recesses and protuberances can be produced accordingly to conform to any shape of a host substrate.

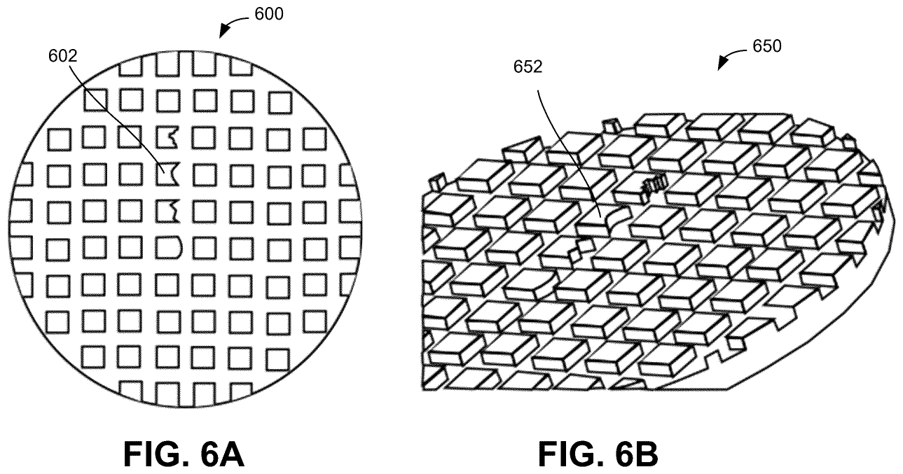

FIG. 6A depicts an example top view of a patterned wafer 600 with a row of dies 602 corresponding to slices for a three-dimensional integrated circuit that have been diced according to a conforming pattern to conform to a non-planar host substrate. FIG. 6B depicts an example isometric view of a row of die edges in a dicing lane on a patterned wafer corresponding to slices for a three-dimensional integrated circuit that have been diced according to a conforming pattern to conform to a non-planar host substrate. A topography transposition may be applied such that a measured or simulated surface map of the host substrate is transposed into a Z-axis-stack-aware slicing plan for the three-dimensional integrated circuit structure. Each slice in the cube is assigned a unique edge profile corresponding to its vertical/horizontal position in the stack. The edge geometry is derived from the host substrates' deformation along the X-Y plane and adjusted slice-by-slice down the Z-Axis. This transposed data may be used to drive photolithographic patterning and plasma etch stages that shape the communication face of each slice. Accordingly, the final assembled cube, once thermally expanded into operating conditions, may then closely match the warped or flattened profile of the host substrate-minimizing physical, electrical, and communication interface gaps.

Such a process may be performed as follows. An X-Y plane topography may be transposed and mapped onto slices in proceeding order down the Z-axis. Individual slices can have different topography cuts as the process advances along the Z-axis. A dimensional mapping of conforming slices may then be used to drive a photolithography process. Plasma dicing may be used to cut the complex, non-linear communication faces patterned by photolithography and derived from the transpositions of the topography of a particular host substrate. Anisotropic etch recipes may be tuned to replicate host-die conforming profiles with high fidelity, enabling undercut-free, curved or stepped sidewalls. In various aspects, accuracy may thus be maintained for slope, depth, curvature, and edge placement of the cut as true to the pattern with minimal deviation between a mask shape and a physical etched result.

Such an approach supports arbitrary in-plane geometries and avoids mechanical stress and chipping from saw-based singulation. Such an approach also enables tight tolerance shaping across multiple slices in parallel as shown in FIG. 6A and FIG. 6B. In this way, communication faces of conforming slices may be patterned using photolithography, with feature geometries transposed from the host substrate's measured or simulated topography. Plasma etching may then be used to transfer these patterns into the wafer. The communication edge can be formed in virtually any geometry supported by the plasma etch process. As shown in FIGS. 6A and 6B, differently-shaped dies 602 and 652 illustrate examples of variable edge profiles that can be achieved within plasma dicing tolerances. The diagrams are intentionally exaggerated to highlight the variation in die geometry and scribe line layout used to enable singulation.

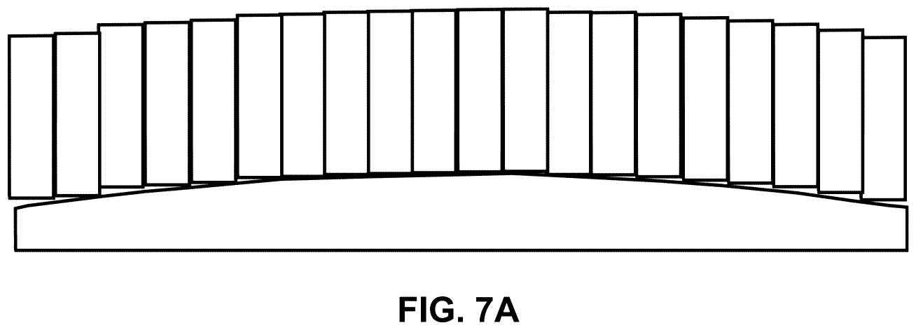

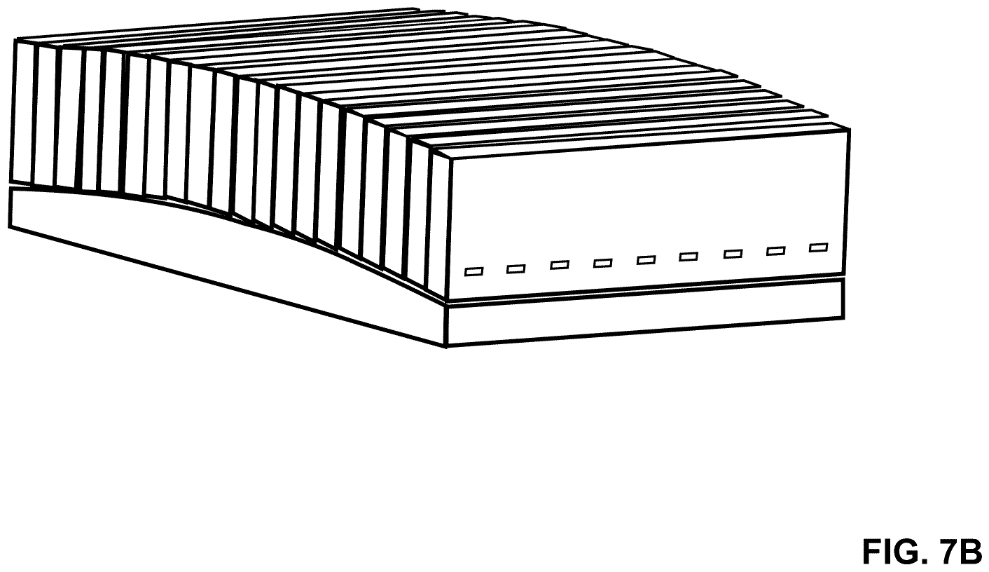

FIG. 7A depicts an example side view of a stack of slices in a three-dimensional integrated circuit disposed upon a host substrate at operating temperature. FIG. 7B depicts an example isometric view of a stack of slices in a three-dimensional integrated circuit disposed upon a host substrate at operating temperature. Y-Z and Z-X plane adjustments may be provided. In addition to conforming along the X-Y interface, host die deformation can be accommodated along the Y-Z and Z-X planes. Y-Z Plane adjustments may also be provided. Slices may undulate vertically in the Y-axis, allowing them to physically lay over convex or concave regions of the host substrate face as seen in FIG. 7A and FIG. 7B. Z-X plane adjusted slices can be laterally offset or staggered across the X-axis to align with the warped edge perimeter of a host substrate. This three-dimensional alignment strategy ensures maximum contact fidelity even when the host substrate is non-flat in multiple axes.

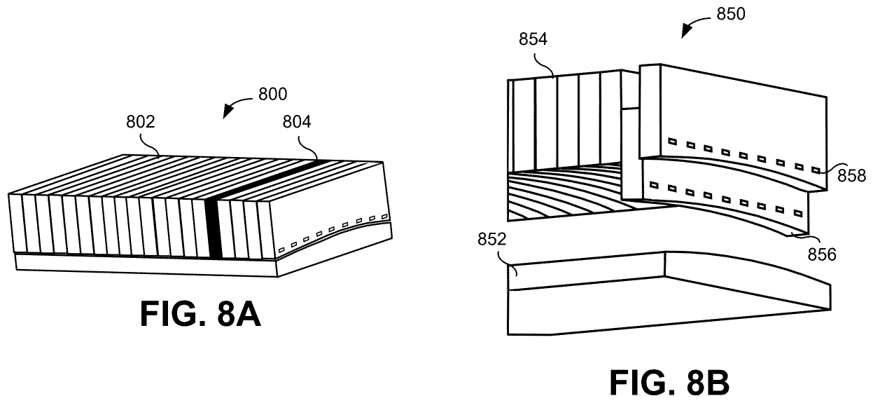

FIG. 8A depicts an example expanded isometric view of a stack 800 of slices 802 in a three-dimensional integrated circuit disposed upon a host substrate at operating temperature with a shim 804. A Z-axis shim 804 may be provided to compensate for Z-direction misalignment caused by variations in slice thickness, chemical mechanical planarization variation, or topography transposition errors. Z-axis shims can be inserted between slices as seen in FIG. 8A. Such shims may be composed of bare Si, polymer, oxide, or low-modulus adhesive materials and serve to realign an input-output plane of a cube with that of the host. Z-axis shims may be uniform thickness across the slice or tapered to correct planar tilt or bow. When forming a concave-shaped conforming cube, a shim may be employed that takes on a voussoir or keystone shaped shim to provide structural integrity of the concave-shaped conforming cube analogously to an arch. Alternatively, when forming a convex-shaped conforming cube, a shim may be employed that takes on an inverted keystone shape to provide structural integrity of the convex-shaped conforming cube, with a downwardly bulging communication surface to communicate with a valley-structure of a host substrate.

FIG. 8B depicts an example expanded isometric view of a stack of slices 850 in a three-dimensional integrated circuit disposed upon a host substrate at operating temperature to illustrate communication faces of conforming slices. The stack of slices 850 may be produced as follows. A host substrate topography dataset represents a captured or simulated shape profile of the host substrate under operating and static conditions. Conforming slices 854 may be produced representing individually patterned three-dimensional integrated circuit slices with shaped communication faces 856. Input-output devices 858 are provided such as inductive coupling devices for wireless integrated circuit interconnection between three-dimensional integrated circuit structure. The topologically compliant communication face is configured to map to an arbitrary topology of a host substrate.

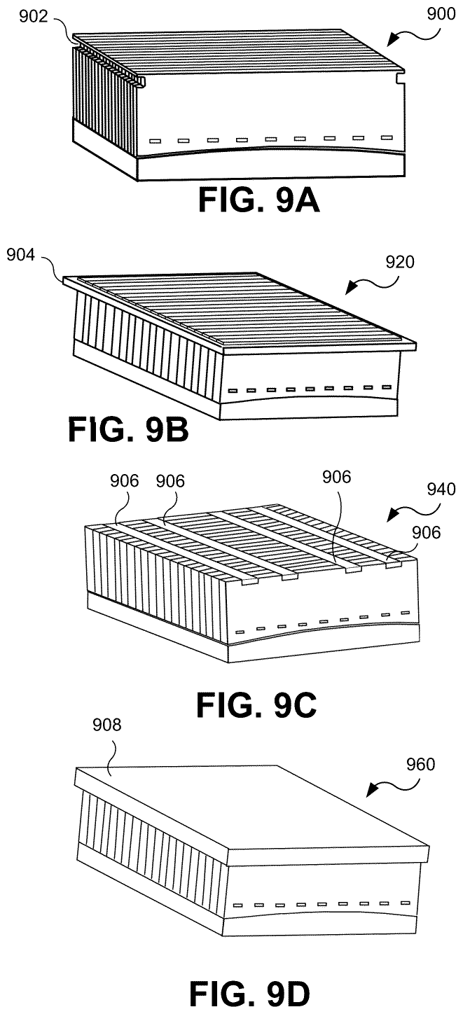

FIG. 9A depicts an example locking groove 902 around a stack of slices 900. Mechanical locking mechanisms 904, 906, and 908 that physically secure and align three-dimensional integrated circuit stacks through etched features (like locking groove 902 and trench mechanism 906 as well as bonding agents, described below. Various connecting mechanisms and locking structures may be provided for connecting and securing slices together to form a three-dimensional heterogeneous integration cube. These locking structures simplify mechanical assembly and long-term stability of the three-dimensional heterogeneous integration cubes without requiring traditional underfill. The approach enables in situ or off-die bonding of structures and enhances structural integrity through etched features. In various aspects, the bonding structures may contain electrically conductive portions that are configured to provide electrical connections between portions of the locked-together stack of integrated circuit slices. Such conductive portions may be formed using various directed doping techniques, such as ion implantation, molecular beam epitaxy, electron beam doping, or laser-induced doping.

In this way, a set of mechanical locking strategies may be provided to physically anchor three-dimensional heterogeneous integration cube slices to themselves and/or a host substrate using precision-etched geometric features and controlled bonding agents. Such systems eliminate a need for traditional underfill or rigid adhesives (between slices) by embedding mechanical interlocks directly into sidewalls of the slices and/or the host environment. These locks may be implemented in various ways, including band locking structures 904, trench locking structures 906, and cap locking structures 908. Depending on a nature of the plane that needs adjustment and mechanical conditions of the topography-conforming, three-dimensional integrated circuit, various in-situ bonding/gluing of the slices or off die bonding/gluing of slices utilizing different forms of locking mechanisms may be applied. Off-die bonding/gluing may involve a host-die jig to mimic a real host substrate topography, to enable proper formation of a communication face with appropriate locking mechanisms

FIG. 9B depicts an example band of formed bonding agent in a groove around a stack of slices in a three-dimensional integrated circuit disposed upon a host substrate at operating temperature. FIG. 9C depicts an example trench of formed bonding agent in a groove around a stack of slices in a three-dimensional integrated circuit disposed upon a host substrate at operating temperature. Trench locking structures may be embedded into the top or base of the cube, which is meant to act as a receiving cavity for injected adhesive seen in FIG. 9C. The trench geometry can be rectangular, V-groove, or T-slot depending on the fill dynamics and retention strength requirements. FIG. 9D depicts an example cap of formed bonding agent in a groove around a stack of slices in a three-dimensional integrated circuit disposed upon a host substrate at operating temperature. Once cured, a capped formed bonding agent may have an advantage of providing a flat surface for building atop the cube, attaching a package lid or other structure for positioning the cube atop the host substrate.

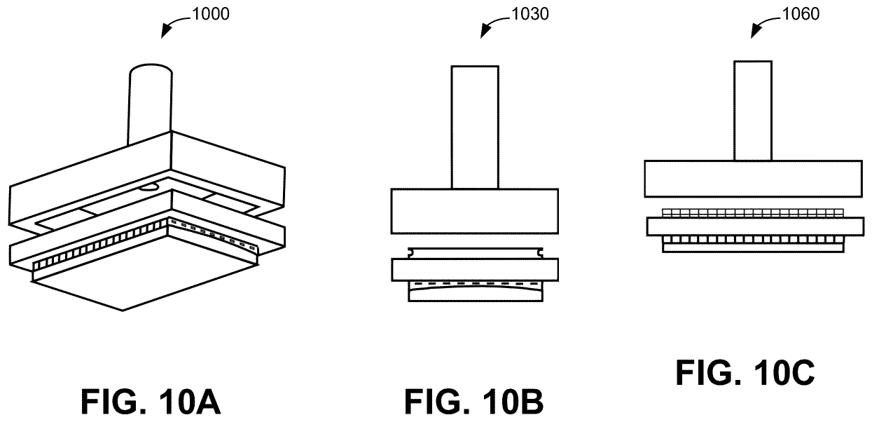

FIG. 10A depicts an isometric view of an example jig and forming device for bonding agent in a groove around a stack of slices in a three-dimensional integrated circuit disposed upon a host substrate at operating temperature. FIG. 10B depicts a front view of an example jig and forming device for bonding agent in a groove around a stack of slices in a three-dimensional integrated circuit disposed upon a host substrate at operating temperature. FIG. 10C depicts a side view of an example jig and forming device for bonding agent in a groove around a stack of slices in a three-dimensional integrated circuit disposed upon a host substrate at operating temperature. Jigs and forming devices may be provided that enable precise, in-situ or off-host deposition of adhesive materials to support conformal, reliable cube integration. Various manufacturing aids such as jigs and forming devices may be provided for to implement various locking mechanisms described above. Such manufacturing aids provide tools for depositing and shaping encapsulants or bonding agents around a three-dimensional integrated circuit cube structure, either during in situ placement on the host substrate or during off-die assembly. Such manufacturing aids may include a sealable base, a feed tube for bonding agent injection, and non-stick surfaces or breakaway designs to avoid unintended adhesion. Such manufacturing aids facilitate precise mechanical alignment and consistent encapsulation of locking features like band locking structures (FIG. 9B), trench locking structures (FIG. 9C), or cap locking structures (FIG. 9D).

A die-edge geometry for each locking structure may incorporate “etched features” that are defined as geometric notches or cutouts etched into the die edge. These features provide an increased mechanical surface area for bonding agents to grip, prevent slippage or delamination under stress, and enable alignment for precision assembly. Etched features may be flat-bottomed, undercut, or asymmetrically shaped to control bonding flow. Etched features may be distributed uniformly or locally at critical stress points and integrated into existing plasma etch stages. Such locking structures are designed to work with a variety of conductive or non-conductive bonding agents or encapsulants. The encapsulants may serve structural, thermal, electrical, or even electromagnetic shielding roles, depending on composition. Possible bonding agents include thermally cured epoxies, UV-curable polymers, reflowable dielectrics, or doped materials for thermal/electrical modulation.

Various modes of integration with a host substrate are contemplated. In various aspects, a locking mechanism can be formed through an in-situ application, which is to say the slices of a cube are locked together once the cube is place onto the host substrate. This allows material to flow directly into the features using capillary or pressure-assisted flow. Off-die application may also be performed, in which a bonding agent is deposited using a jig or forming tool and allowed to partially cure or take shape before being brought into the contact with the host substrate. This is ideal for batch processing, pre-alignment, or staged cube stacking.

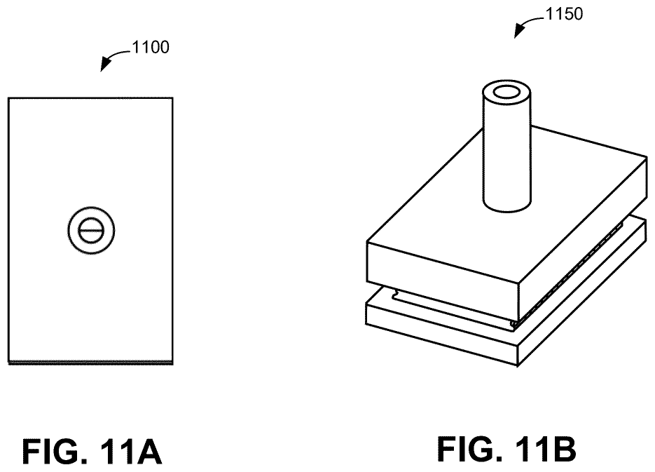

FIG. 11A depicts a side view of an example jig and forming device for bonding agent in a groove around a stack of slices in a three-dimensional integrated circuit disposed upon a host substrate at operating temperature. FIG. 11B depicts another isometric view of an example jig and forming device for bonding agent in a groove around a stack of slices in a three-dimensional integrated circuit disposed upon a host substrate at operating temperature. Mechanical forming tools are designed to precisely deposit and shape bonding agents around a three-dimensional heterogeneous integration cube or individual slices either in situ or off-die in a staging environment.

The jig ensures consistent alignment with etched locking features such as the trench locking structures, band locking structures, and cap locking structures, enabling secure, repeatable integration of the cube to its host or neighboring cubes. A rigid foundation with a cavity that aligns to the cube's dimensions may contain Z-stops or support pillars to ensure vertical placement control. Non-stick or selectivity adhesive surfaces that define the outer geometry of the bonding material can include removable inserts or spring-loaded gates that conform to the sidewall notches (etched feature, trenches, etc.) Feed port/injection channels may be located strategically to inject bonding agent into the cavity in a controlled volume and flow pattern. Optional ports for vacuum venting or pressure equalization may be provided during encapsulant dispensing. Release and disassembly features may be provided that are designed to allow non-destructive removal after partial or full cure. These may use breakaway, sacrificial layers, elastomeric coatings, or chemically inert liners.

Various operational modes may be provided for off die forming. A three-dimensional heterogeneous integration cube is placed inside a jig and bonding agent is injected around its base and/or sides. After partial or full cure or shaping, the structure is removed and placed onto a host substrate. This approach enables batch processing, re-workability, and pre-bond quality control. By contrast, with in-situ encapsulation, a jig is temporarily placed over the cube, then placed down on host. Bonding agent is dispensed to form mechanical interlock without die shift. Such an approach may be useful for single-unit alignment and when the host topography is substantially irregular.

A jig may be composed of polytetrafluoroethylene (PTFE), polyetheretherketone (PEEK), or other chemically inert polymers. Precision-machined silicon or quartz may be employed for cleanroom integration. Three-dimensionally-printed, sacrificial materials may be used for one-time-use applications. The feed tube of a forming device may allow an encapsulant, epoxy, or bonding agent to be fed into a forming device while the bottom of the forming device was mated down on the top face of jig, creating a seal that keeps encapsulant, epoxy, or bonding agent in place. In various aspects, a jig is either a breakaway device or incorporates a non-stick material as to avoid permanent attachment to the three-dimensional integrated circuit structure. These same principals would to the forming devices as well.

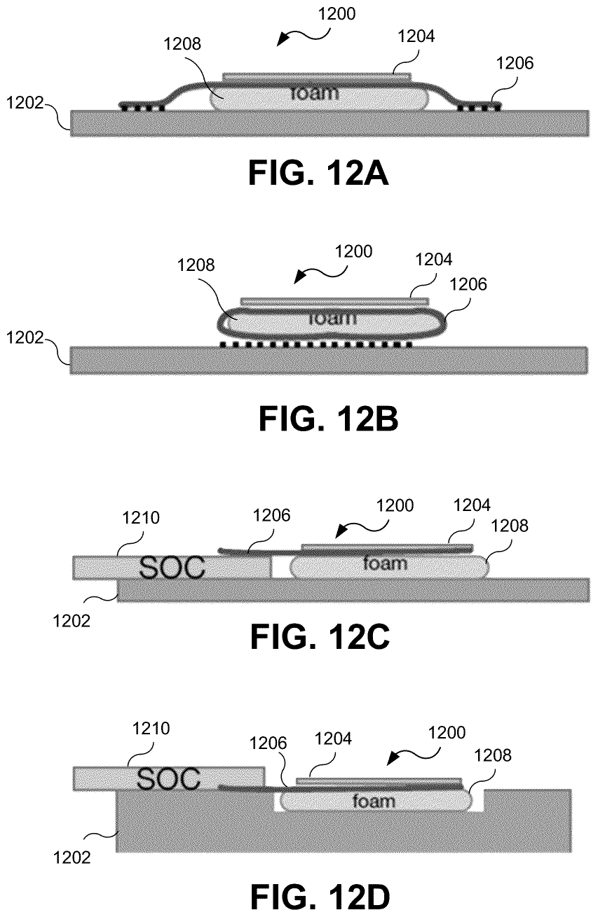

FIG. 12A depicts an example flexible interface 1200 for flexibly supporting a stack of slices in a three-dimensional integrated circuit with a laterally connected flexible interface structure connected laterally to a substrate 1202. FIG. 12B depicts another example flexible interface 1200 for flexibly supporting a stack of slices in a three-dimensional integrated circuit with a laterally connected interface structure connected to a substrate 1202. FIG. 12C depicts yet another flexible interface 1200 for flexibly supporting a stack of slices in a three-dimensional integrated circuit with a laterally connected interface structure connected to a substrate 1202. FIG. 12D depicts another flexible interface for flexibly supporting a stack of slices in a three-dimensional integrated circuit with a laterally connected interface structure connected to a substrate 1202.

Flexible adaptive substrate interfaces 1200 may be provided that use thin silicon on elastomeric support layers to conform to warped substrates, while maintaining electrical contact through latterly extended interconnects. These mechanisms allow reversible compression and shape accommodation without rigid bonding. Flexible adaptive substrate interface connections 1200 provide mechanisms for interfacing flexible, ultra-thin silicon dies 1204 with non-planar three-dimensional heterogeneous integration structures using a combination of compliant support materials and laterally extended electrical interconnects 1206.

Flexible interface 1200 enables flexible silicon die 1204 mounted on a flex circuit 1206, supported by foam or elastomer 1208, to conform to warped or stepped host surfaces while maintaining electrical or wireless contact across an air or encapsulant interface. This structure provides mechanical compliance, thermal stress absorption, and signal continuity without requiring rigid bonding, surface flattening, or mechanical manipulation either between slices or between a cube of slices and a host substrate. In various aspects, adaptive integration is provided between vertically-stacked three-dimensional heterogeneous integration structures with warped or thermally active host substrates, improving mechanical fit and signal integrity across a range of operating conditions. Such an approach reduces the need for substrate flatness, enabling broader substrate selection flexibility, and materials compatibility in various ranges of operating temperatures.

Flexible adaptive substrate interface connections enable three-dimensional heterogeneous integration systems to mechanically and electrically interface with warped, stepped, or otherwise non-planar surfaces without requiring reflow, underfill, or mechanical force. The use of flexible silicon and complaint backing layers provides natural alignment, absorbs thermal mismatch strain, and supports both physical and wireless electrical coupling. This approach expands substrate compatibility, improves integration yield, and simplifies assembly for advanced heterogeneous and chiplet-based architectures. Such flexible adaptive substrate interfaces enable ultra-thin, flexible silicon dies to mechanically and electrically interface with warped or stepped three-dimensional heterogeneous integration surfaces by mounting the die onto a flex circuit substrate. This substrate provides both signal routing and mechanical support and may include compliant backing layers such as foam or an elastomer to accommodate for the topography of a three-dimensional integrated circuit. The result is a mechanically adaptive, electrically continuous structure capable of maintaining contact across non-planar surfaces without requiring rigid bonding or surface flattening.

A flexible interface 1200 includes various components as shown in FIGS. 12A-12D. An ultra-thin, flexible silicon die 1204 may be provided. A compliant support layer, e.g., elastomer or foam 1208 may be provided. A laterally extended interconnect structure 1206 may be provided that bridges an electrical interface gap. In various aspects, ultra-thin, silicon die 1204 used in the flexible adaptive substrate interface connector system may be formed using one of several thinning or layer-release processes as follows. Trench-protect-etch-release (TPER) mechanisms involve defining one or more die boundaries and releasing thin dies using a combination of lithographic trenching and selective etching. Ion slicing involves hydrogen ion implantation and thermal annealing to cleave an ultra-thin layer of silicon for transfer. Mechanical exfoliation involves stress-based delamination using plasma-enhanced chemical vapor deposition (PECVD) layers or metal seeding. Plasma-assisted epitaxial lift-off involves a bottom-up growth of a thin silicon layer on a sacrificial release layer. This process grows silicon on a sacrificial nanogap or porous release layer for waste-free detachment. The result is an ultra-thin die (<50 um) that remains functionally robust but mechanically bendable.

A flex circuit integration process may be provided in which a released die is then bonded to a flex circuit substrate, typically including a polyimide or other high-temp polymer base. A patterned copper or gold interconnect may be provided for lateral signal routing and/or input-output generation. Passivation layers for mechanical protection and environmental isolation may be provided. The flex circuit serves as a signal conduit between the die and host interface.

Flexible interfaces 1200 provide a mechanically adaptive base that can conform to stepped or warped topography and can be treated as a carrier for assembly operations. To further support topography accommodation, a compliant layer may be embedded behind or beneath the flex circuit. Corresponding materials may include foam or elastomers such as polydimethylsiloxane (PDMS), low-modulus polyurethane, etc. The compliant layer may be held in place in connection with a thermally stable, compressible adhesive film or backing. Such a backing allows the entire flexible adaptive substrate interface assembly to dynamically conform to the thin die and three-dimensional integrated circuit during integration or under thermomechanical stress. It also provides shock absorption and Z-axis stress relief.

Coupling mechanisms may be provided in the form of a connection between the flexible die, flex circuit, three-dimensional integrated circuit, and host may be achieved through physical contact interconnects from a flexible die to the host by laterally extended metal traces, embedded in the flex circuit. In this way, signals from the die's bond pads, may be routed through the flex circuit, to the landing sites located on host substrate 1202. Flexible die to three-dimensional integrated circuit contact may be established via microbumps or other electrical connections.

A wireless interface may be provided between flexible interface 1200 and a three-dimensional integrated circuit. Capacitive pads or planar inductors on the flex die allow signal and/or power transfer across an air or encapsulant gap o the three-dimensional integrated circuit. Flexible adaptive substrate interface assemblies may be integrated in various ways: In situ attachment involves placing the flexible circuit and die directly on to the host surface. Off-die staging may also be provided in which flexible adaptive substrate interface structures are preassembled and transferred to the host system. Such flexible interfaces support pre-screening, rework, and modular cube configurations. Such flexible interfaces have the benefits of mitigating a need for rigid bonding and surface flattening and absorbs mechanical and thermal mismatch stress between three-dimensional integrated circuits and a system-on-a-chip, while maintaining signal integrity across warped, bowed, or stepped surfaces.

Unless explicitly specified, the term “transmit” encompasses both direct (point-to-point) and indirect transmission (via one or more intermediary points). Similarly, the term “receive” encompasses both direct and indirect reception.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art.

The terms “at least one” and “one or more” may be understood to include any integer number greater than or equal to one, i.e., one, two, three, four, [ . . . ], etc. The term “a plurality” or “a multiplicity” may be understood to include any integer number greater than or equal to two, i.e., two, three, four, five, [ . . . ], etc. The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The terms “processor” as used herein may be understood as any kind of technological entity that allows handling of data. The data may be handled according to one or more specific functions that the processor execute. Further, a processor as used herein may be understood as any kind of circuit, e.g., any kind of analog or digital circuit. A processor may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions may also be understood as a processor. It is understood that any two (or more) of the processors detailed herein may be realized as a single entity with equivalent functionality or the like, and conversely that any single processor detailed herein may be realized as two (or more) separate entities with equivalent functionality or the like.

The following examples pertain to aspects of the configuration proposed herein.

Example 1 is a three-dimensional integrated circuit. The three-dimensional integrated circuit includes a plurality of conformal integrated circuit slices stacked one upon another; wherein each of the plurality of conformal integrated circuit slices comprises: a communication face defining a communication surface configured to conform to a portion of a topography of a non-planar host substrate; and a plurality of input-output devices configured to communicate with a corresponding plurality of host input-output devices within the non-planar host substrate.

In Example 2, the subject matter of Example 1 can optionally include that the plurality of input-output devices includes a plurality of non-contact input-output devices, wherein the corresponding plurality of host-side input-output devices includes the corresponding plurality of host-side non-contact input-output devices, and wherein the plurality of non-contact input-output devices is configured to wirelessly communicate with the corresponding plurality of host-side non-contact input-output devices within the non-planar host substrate.

In Example 3, the subject matter of Examples 1 or 2 can optionally include that the plurality of non-contact input-output devices includes a plurality of inductive couplers and associated driver circuitry.

In Example 4, the subject matter of Examples 1 to 3 can optionally include that the input-output device offsets define a Manhattan geometry of respective distances from the communication surface.

In Example 5, the subject matter of Examples 1 to 4 can optionally include that the the portion of the topography of non-planar host substrate is substantially convex.

In Example 6, the subject matter of Examples 1 to 5 can optionally include that the portion of the topography of non-planar host substrate is substantially concave.

In Example 7, the subject matter of Examples 1 to 6 can optionally include an etched feature in a surface portion of a plurality of exterior slices of the three-dimensional integrated circuit.

In Example 8, the subject matter of Example 7 can optionally include that the etched feature includes a band structure at least partially circumferentially encompassing the plurality of conformal integrated circuit slices.

In Example 9, the subject matter of Example 8 can optionally include that can optionally include that the band structure includes a conductive portion configured to provide an electrical connection between a subset of the plurality of conformal integrated circuit slices.

In Example 10, the subject matter of Example 7 can optionally include that the etched feature includes a plurality of trench structures laterally spanning a top portion of the three-dimensional integrated circuit.

In Example 11, the subject matter of Example 10 can optionally include that the trench structures include a conductive portion configured to provide an electrical connection between a subset of the plurality of conformal integrated circuit slices.

In Example 12, the subject matter of Examples 1 to 11 can optionally include a locking structure deposited within the etched feature to lock the plurality of integrated slices in place.

In Example 13, the subject matter of Examples 1 to 12 can optionally include that the plurality of non-contact input-output devices includes a plurality of inductive couplers and associated driver circuitry.

In Example 14, the subject matter of Examples 1 to 13 can optionally include that the plurality of host-side non-contact input-output devices includes a plurality of host inductive couplers and associated driver circuitry.

In Example 15, the subject matter of Examples 1 to 14 can optionally include a mechanically adaptive interface configured to couple the plurality of integrated circuit slices to the host substrate, the mechanically adaptive interface including: a flexible semiconductor interface layer including a plurality of interface input-output devices; a flex circuit substrate configured to route electrical signals from the plurality of interface input-output devices to the host substrate; and a compliant layer configured to mechanically-adaptively support the flexible semiconductor interface.

In Example 16, the subject matter of Example 15 can optionally include that the plurality of interface non-contact input-output devices includes a plurality of host inductive couplers and associated driver circuitry.

In Example 17, the subject matter of Examples 15 or 16 can optionally include that the flexible semiconductor interface layer includes an ultra-thin silicon layer including: a trench-protect-etch-release structure; a mechanical exfoliation structure; or a plasma-assisted epitaxial lift-off structure.

In Example 18, the subject matter of Examples 15 to 17 can optionally include that the flex circuit substrate includes high-temp polymer base and a patterned copper or gold interconnect configured to provide lateral signal routing.

In Example 19, the subject matter of Examples 15 to 18 can optionally include that the compliant layer includes an elastomer.

In Example 20, the subject matter of Examples 15 to 19 can optionally include that the elastomer includes polydimethylsiloxane or low-modulus polyurethane.

Example 21 is a method of manufacturing a three-dimensional integrated circuit. The method includes: forming a plurality of conformal integrated circuit slices by: forming a communication face of each of the plurality of conformal integrated circuit slices, the communication face defining a communication surface configured to fit loosely with, at room temperature, and to conform to, at operating temperatures, a portion of a topography of a non-planar host substrate; and forming a plurality of input-output devices configured to communicate with a corresponding plurality of host input-output devices within the non-planar host substrate; and stacking the plurality of conformal integrated circuit slices one upon another.

In Example 22, the subject matter of Example 21 can optionally include optically scanning a surface of a representative host substrate at operating temperature to determine the topography of the non-planar host substrate.

In Example 23, the subject matter of Examples 21 or 22 can optionally include forming the plurality of input-output devices in a plane that is substantially tangential to a local maximum depth of the communication surface.

In Example 24, the subject matter of Examples 21 to 23 can optionally include forming the plurality of input-output devices along a curve defining input-output device offsets that are substantially equidistant from the communication surface.

In Example 25, the subject matter of Example 24 can optionally include that the input-output device offsets define a Manhattan geometry of respective distances from the communication surface.

In Example 26, the subject matter of Examples 21 to 25 can optionally include that the portion of the topography of non-planar host substrate is substantially convex.

In Example 27, the subject matter of Examples 21 to 26 can optionally include that the portion of the topography of non-planar host substrate is substantially concave.

In Example 28, the subject matter of Examples 21 to 27 can optionally include forming an etched feature in a surface portion of a plurality of exterior slices of the three-dimensional integrated circuit.

In Example 29, the subject matter of Example 28 can optionally include that the etched feature includes a band structure at least partially circumferentially encompassing the plurality of conformal integrated circuit slices.

In Example 30, the subject matter of Example 29 can optionally include that the band structure includes a conductive portion configured to provide an electrical connection between a subset of the plurality of conformal integrated circuit slices.

In Example 31, the subject matter of Example 28 can optionally include that the etched feature includes a plurality of trench structures laterally spanning a top portion of the three-dimensional integrated circuit.

In Example 32, the subject matter of Example 31 can optionally include that the trench structures include a conductive portion configured to provide an electrical connection between a subset of the plurality of conformal integrated circuit slices.

In Example 33, the subject matter of Examples 21 to 32 can optionally include forming a locking structure deposited within the etched feature to lock the plurality of integrated slices in place.

In Example 34, the subject matter of Examples 21 to 33 can optionally include that the plurality of input-output devices includes a plurality of inductive couplers and associated driver circuitry.

In Example 35, the subject matter of Examples 21 to 34 can optionally include that the plurality of host input-output devices includes a plurality of host inductive couplers and associated driver circuitry.

In Example 36, the subject matter of Examples 21 to 35 can optionally include that forming the communication face of each of the plurality of conformal integrated circuit slices further includes laterally offsetting plane adjusted slices to be staggered across an x-axis to align with a warped edge perimeter of the non-planar host substrate.

In Example 37, the subject matter of Examples 21 to 36 can optionally include that forming a plurality of conformal integrated circuit slices further includes: inserting one or more z-axis shims between at least two of the plurality of conformal integrated circuit slices.

Example 38 is a method. The method includes: forming a mechanically adaptive interface configured to couple the plurality of integrated circuit slices to the host substrate, the mechanically adaptive interface being formed by: forming a flexible semiconductor interface layer including a plurality of interface input-output devices; forming a flex circuit substrate configured to route electrical signals from the plurality of interface input-output devices to the host substrate; and forming a compliant layer configured to mechanically-adaptively support the flexible semiconductor interface.

In Example 39, the subject matter of Examples 21 to 33 can optionally include that the plurality of interface input-output devices includes a plurality of host inductive couplers and associated driver circuitry.

In Example 40, the subject matter of Examples 21 to 33 can optionally include that forming the flexible semiconductor interface layer further includes: forming a trench-protect-etch-release structure; forming a mechanical exfoliation structure; or forming a plasma-assisted epitaxial lift-off structure.

Example 41 is a device. The device includes: a flexible semiconductor interface layer including a plurality of interface input-output devices; a flex circuit substrate configured to route electrical signals from the plurality of interface input-output devices to the non-planar host substrate; and a compliant layer configured to mechanically-adaptively support the flexible semiconductor interface.

In Example 42, the subject matter of Example 41 can optionally include that the flexible semiconductor interface layer includes an ultra-thin flexible silicon die.

What is claimed is:

1. A device comprising:
a plurality of conformal integrated circuit slices stacked one upon another;
wherein the plurality of conformal integrated circuit slices comprises:
a communication face defining a communication surface configured to conform to a portion of a topography of a non-planar host substrate; and
a plurality of input-output devices configured to communicate with a corresponding plurality of host-side input-output devices within the non-planar host substrate.

2. The device of claim 1, wherein the plurality of input-output devices comprises a plurality of non-contact input-output devices, wherein the corresponding plurality of host-side input-output devices comprises the corresponding plurality of host-side non-contact input-output devices, and wherein the plurality of non-contact input-output devices is configured to wirelessly communicate with the corresponding plurality of host-side non-contact input-output devices within the non-planar host substrate.

3. The device of claim 2, wherein the plurality of non-contact input-output devices comprises a plurality of inductive couplers and associated driver circuitry.

4. The device of claim 1, wherein the plurality of input-output devices is formed in a plane that is substantially tangential to a local maximum depth of the communication surface.

5. The device of claim 1, wherein the plurality of input-output devices is formed along a curve defining input-output device offsets that are substantially equidistant from the communication surface.

6. The device of claim 1, wherein the corresponding plurality of host-side input-output devices comprises a plurality of electrical contacts and associated driver circuitry.

7. The device of claim 1 further comprising a mechanically adaptive interface configured to couple the plurality of integrated circuit slices to the non-planar host substrate, the mechanically adaptive interface comprising:
a flexible semiconductor interface layer comprising a plurality of interface input-output devices;
a flex circuit substrate configured to route electrical signals from the plurality of interface input-output devices to the non-planar host substrate; and
a compliant layer configured to mechanically-adaptively support the flexible semiconductor interface.

8. The device of claim 7, wherein the plurality of interface input-output devices comprises a plurality of host inductive couplers and associated driver circuitry.

9. The device of claim 7, wherein the flexible semiconductor interface layer comprises an ultra-thin silicon layer comprising:
a trench-protect-etch-release structure;
a mechanical exfoliation structure; or
a plasma-assisted epitaxial lift-off structure.

10. The device of claim 7, wherein the flex circuit substrate comprises high-temp polymer base and a patterned copper or gold interconnect configured to provide lateral signal routing.

11. The device of claim 7, wherein the compliant layer comprises polydimethylsiloxane or low-modulus polyurethane.

12. A method comprising:
forming a plurality of conformal integrated circuit slices by:
forming a communication face the plurality of conformal integrated circuit slices, the communication face defining a communication surface configured to fit loosely with, at room temperature, and to conform to, at operating temperatures, a portion of a topography of a non-planar host substrate; and
forming a plurality of input-output devices configured to communicate with a corresponding plurality of host-side input-output devices within the non-planar host substrate; and
stacking the plurality of conformal integrated circuit slices one upon another.

13. The method of claim 12, further comprising:
optically scanning a surface of a representative host substrate at operating temperature to determine the topography of the non-planar host substrate.

14. The method of claim 12 further comprising:
forming the plurality of input-output devices in a plane that is substantially tangential to a local maximum depth of the communication surface.

15. The method of claim 12, wherein forming the communication face of each of the plurality of conformal integrated circuit slices further comprises laterally offsetting plane adjusted slices to be staggered across an x-axis to align with a warped edge perimeter of the non-planar host substrate.

16. The method of claim 12 further comprising:
etching an etched feature in a surface portion of a plurality of exterior slices of a three-dimensional integrated circuit.

17. The method of claim 16, wherein the etched feature comprises a band structure at least partially circumferentially encompassing the plurality of conformal integrated circuit slices.

18. The method of claim 17, wherein the band structure comprises a conductive portion configured to provide an electrical connection between a subset of the plurality of conformal integrated circuit slices.

19. A device comprising:
a flexible semiconductor interface layer comprising a plurality of interface input-output devices;
a flex circuit substrate configured to route electrical signals from the plurality of interface input-output devices to the non-planar host substrate; and
a compliant layer configured to mechanically-adaptively support the flexible semiconductor interface.

20. The device of claim 19, wherein the flexible semiconductor interface layer comprises an ultra-thin flexible silicon die.
